(19) United States
(12) Patent Application Publication
(10) Pub. No.: US 2024/0425355 A1
(43) Pub. Date: Dec. 26, 2024

(54) Three-axis Gyroscope

(71) Applicant: SENSORTEK TECHNOLOGY CORP., Hsinchu County (TW)

(72) Inventors: Shih-Hsiung TSENG, Hsinchu County (TW); Shih-Wei LEE, Hsinchu County (TW); Chao-Shiun WANG, Hsinchu County (TW)

(21) Appl. No.: 18/242,132

(22) Filed: Sep. 5, 2023

Related U.S. Application Data
(60) Provisional application No. 63/374,448, filed on Sep. 2, 2022.

(51) Int. Cl. B81B 3/00; G01C 19/5712

(52) U.S. Cl. CPC B81B 3/0037; G01C 19/5712; B81B 2201/0242; B81B 2203/0145; B81B 2203/0307; B81B 2203/04; B81B 2203/056; B81B 2203/058

(57) ABSTRACT

The present application provides a three-axis gyroscope, which comprises a substrate on which a first plate element, a second plate element, a third plate element, a first drive module, and a second drive module are disposed. The first driving module, the first plate element, the second plate element, the third plate element and the second driving module are disposed in an axial direction. Thereby, problems caused by use of frames and coupling flexible structures of three-axis gyroscopes available now may be solved effectively.

### FIELD OF THE INVENTION

The present application relates to a gyroscope, especially to a gyroscope capable of sensing three-axis angular velocity.

### BACKGROUND OF THE INVENTION

In a vibrating gyroscope, Coriolis force generated during the rotation of a proof mass vibrating at high frequency driven by a base is used to detect angular velocity. The vibrating gyroscope has advantages of stable performance, simple structure, high reliability, etc. The most common vibrating gyroscopes includes tuning fork vibrating gyroscope, piezoelectric vibrating gyroscope, capacitive vibrating gyroscope, shell vibrating gyroscope, etc.

Currently, capacitive vibrating gyroscopes manufactured with microelectromechanical systems (MEMS) is available. In order to detect three-axis angular velocity, most gyroscopes include at least four proof masses (also called mass plates). To make the proof masses vibrate in two different directions, complicated structures are provided by currently existing techniques. For example, additional parts such as a drive frame and a rotary frame are required, which leads to larger volumes of the capacitive vibrating gyroscope. Thus, chips with larger size are used, and production or usage costs are further increased.

In order to solve above problems of the currently existing techniques, the applicants have filed US Pat. Pub. No. US20220026210A1, in which a gyroscope structure is provided. A frame is disposed on a substrate and each flexible element is connected with three mass plates correspondingly. A sensing element is disposed on the substrate or the mass plates to sense movement and rotation of the mass plates. A driving element is provided for actuating a corresponding plate. Thereby, a three-axis gyroscope with reduced volume is provided.

Although the number of the proof masses and frames is reduced in the above filed application, the frame is still included in the gyroscope. The existence of the frame not only increases the complexity of arranging of the flexible elements or discrete drive electrodes but also limits the range of movement of the proof masses. Thus, effective sensing area of the proof mass is reduced. Some of the above problems may be solved by using the flexible element with smaller cross section. However, the flexible element would then require finer line width, which would increase the production cost of the flexible elements and reduce the yield rate.

Thus, based on the above, the applicant has conducted research and development to provide a further improved three-axis gyroscope . . .

### SUMMARY

Therefore, it is an object of the present application to provide a three-axis gyroscope that solves various problems caused by the use of frames and related coupling flexible structures mentioned above.

In order to achieve the above object, a three-axis gyroscope according to the present application includes a substrate on which a first plate element, a second plate element, a third plate element, a first drive module and a second drive module are disposed. The first drive module, the first plate element, the second plate element, the third plate element, and the second drive module are disposed along a first axial direction. The first plate element is connected with the second plate element by a first flexible member while the third plate element is connected with the second plate element by a second flexible member. The first flexible member and the second flexible member are located on two sides of the second plate element correspondingly in the first axial direction. The first drive module is connected with the first plate element by a third flexible member for driving the first plate element to move reciprocally in a second axial direction, which is perpendicular to the first axial direction. The second drive module is connected with the third plate element by a fourth flexible member for driving the third plate element to move reciprocally in the second axial direction.

The present application provides another three-axis gyroscope, in which the first plate element, the first drive module, the second plate element, the second drive module, and the third plate element are disposed along the first axial direction.

Generally, the three-axis gyroscope according to the present application is designed to sense three-axis angular velocity without using additional frames. The above structure effectively solves various problems caused by the use of the frames and related coupling flexible structures in conventional gyroscopes. The present three-axis gyroscope can be combined with simplified coupling flexible structures to reduce the overall area of the gyroscope. Moreover, the reduced number of flexible members and the frame-less design not only optimize the effective sensing area of the original plates but also allow the original flexible members to have better fabrication tolerance and avoid significant reduction in line width. Thus, production cost is reduced, and yield rate is improved.

### BRIEF DESCRIPTION OF THE DRAWINGS

FIG. 1 is a schematic diagram of an embodiment according to the present application;

FIG. 2 is a schematic drawing showing the action of an embodiment of a three-axis gyroscope according to the present application;

FIG. 3A is a schematic drawing showing sensing of rotational motion in a first axial direction of an embodiment according to the present application;

FIG. 3B is a schematic drawing showing sensing of rotational motion in a second axial direction of an embodiment according to the present application;

FIG. 3C is a schematic drawing showing sensing of rotational motion in a third axial direction of an embodiment according to the present application;

FIG. 4 is a schematic drawing showing the arrangement of sensing electrodes in an embodiment according to the present application;

FIG. 5 is a a schematic drawing showing the structure of an embodiment according to the present application;

FIG. 6 is a a schematic drawing showing another structure of an embodiment according to the present application;

FIG. 7 is a schematic drawing showing the action of another embodiment of a three-axis gyroscope according to the present application.

### DETAILED DESCRIPTION

In order to understand features and functions of the present application more clearly, please refer to the following embodiments, related figures and descriptions.

The present application provides a three-axis gyroscope which includes a substrate, a first plate element, a second plate element, a third plate element, and a first drive module and a second module both used for driving the above plates. The first plate element, the second plate element, and the third plate element are disposed on the substrate and used as proof masses. The first plate element, the second plate element, and the third plate element are connected by flexible members while the first drive module and the second drive module are respectively connected with the first plate element and the third plate element by flexible members. More importantly, the first, the second, and the third plate elements, and the first and the second drive modules are disposed along an axial direction. Thereby, sensing of three-axis angular velocity is performed by sensors that detect motions (including in-plane and out-of-plane motions) of the plates such as translation and rotation, without arrangement of additional frames. The above structure solves various problems caused by the use of frames and related coupling flexible structures in conventional gyroscopes.

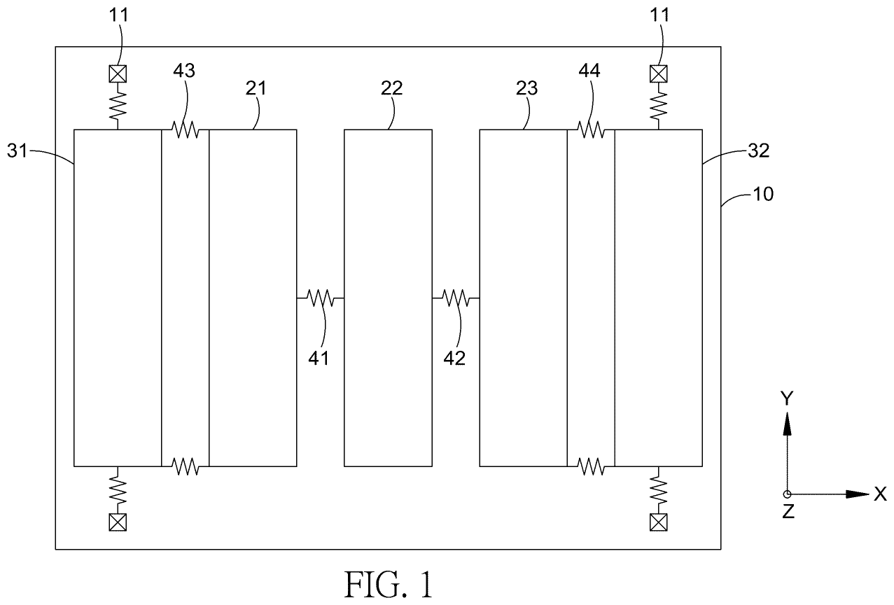

Referring to FIG. 1, a first embodiment of a three-axis gyroscope according to the present application includes a substrate 10 on which a first plate element 21, a second plate element 22, a third plate element 23, a first drive module 31, and a second drive module 32 are disposed. The substrate 10 may be a silicon substrate, but is not limited to this in the first embodiment.

Along a first axial direction X, the second plate element 22 is disposed between the first plate element 21 and the third plate element 23. The first drive module 31 is disposed on one side of the first plate element 21 away from the second plate element 22 in the first axial direction X, while the second drive module 32 is disposed on one side of the third plate element 23 away from the second plate element 22 in the first axial direction X. Thereby, the first drive module 31, the first plate element 21, the second plate element 22, the third plate element 23 and the second drive module 32 are disposed along the first axial direction X.

As described in more detail below, an outer edge of the first plate element 21 is connected with an outer edge of the second plate element 22 by a first flexible member 41. An outer edge of the third plate element 23 is connected with an outer edge of the second plate element 22 by a second flexible member 42. The first flexible member 41 and the second flexible member 42 are located on two sides of the second plate element 22 correspondingly in the first axial direction X. The first drive module 31 is connected with the first plate element 21 by at least one third flexible member 43 for driving the first plate element 21. The first drive module 31 is fixed on the substrate 10 by at least one positioning member 11 such as a flexible member or an anchor point. The first drive module 31 and the second plate element 22 are disposed on two sides of the first plate element 21 correspondingly in the first axial direction X. The second drive module 32 is connected with the third plate element 23 by at least one fourth flexible member 44 for driving the third plate element 23. The second drive module 32 is fixed on the substrate 10 by at least one positioning member 11 such as a flexible member or an anchor point. The second drive module 32 and the second plate element 22 are disposed on two sides of the third plate element 23 correspondingly along the first axial direction X.

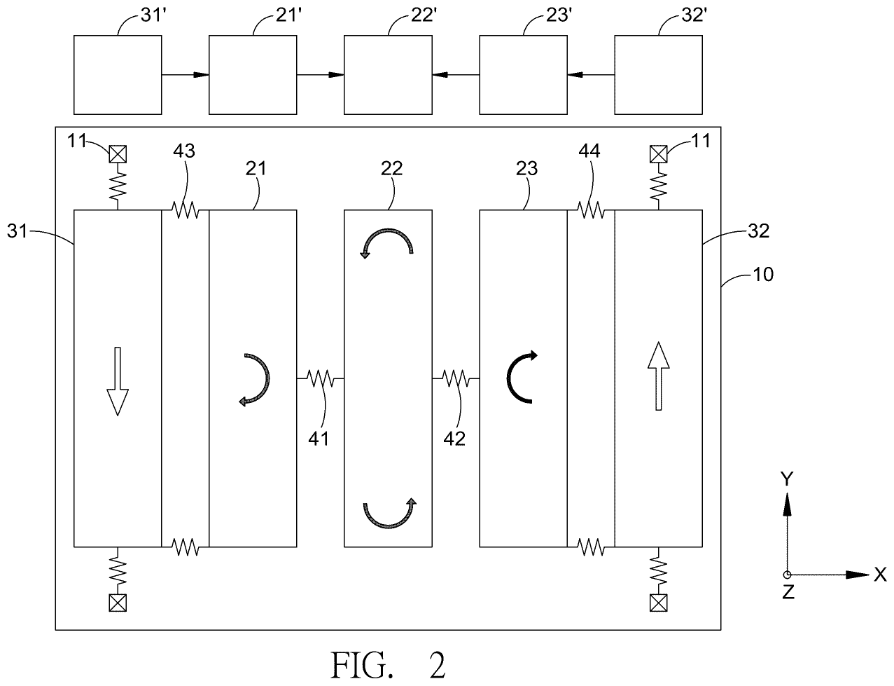

Referring to FIG. 2, which provides a schematic drawing showing how the first embodiment of the three-axis gyroscope works. A second axial direction Y is perpendicular to the first axial direction X while a third axial direction Z is perpendicular to both the first axial direction X and the second axial direction Y. The first drive module 31 is connected with the first plate element 21 by the third flexible member 43 for driving the first plate element 21 to move forward and backward alternately in the second axial direction Y. The second drive module 32 is connected with the third plate element 23 by the fourth flexible member 44 for driving the third plate element 23 to reciprocate in the second axial direction Y. In a preferred embodiment, the direction in which the first plate element 21 is driven to move by the first drive module 31 is opposite to the direction in which the third plate element 23 is driven to move by the second drive module 32. This means there is a phase difference of 180 degrees between the two directions.

In order to sense Coriolis force in the three axes XYZ of the three-axis gyroscope, vibrations of proof masses in at least two different directions are required. In this embodiment, the first plate element 21 and the third plate element 23 are driven to reciprocate in the same direction—the second axial direction Y. The movement of the two plates 21, 23 has the phase difference of 180 degrees to form vibrations in opposite directions. FIG. 2 is a schematic drawing showing transfer of driving force. In this embodiment, the first drive module 31′ and the second drive module 32′ respectively actuate the first plate element 21′ and the third plate element 23′ from two sides, and then driving forces are transferred from the outside to the inside to indirectly drive the second plate element 22′.

It should be noted that the first plate element 21 and the third plate element 23 may be used as a two-axis sensor module, while the second plate element 22 may be used as a single-axis sensor module. The first plate element 21 of the two-axis sensor module is connected with the second plate element 22 of the single-axis sensor module and the first drive module 31 respectively by the first flexible member 41 and the third flexible member 43 which are disposed asymmetrically. The third plate element 23 is connected with the second plate element 22 of the single-axis sensor module and the second drive module 32 respectively by the second flexible member 42 and the fourth flexible member 44 which are disposed asymmetrically. Thereby, the first plate element 21 and the third plate element 23 have a first rotational motion respectively while being driven by the first drive module 31 and the second drive module 32 respectively. At the same time, the two-axis sensor module drives the single-axis sensor module through the first and the second flexible members 41, 42 and then the second plate element 22 is further driven to have a second rotational motion. Therefore, the three plates 21, 22, 23 have the two rotational motions respectively.

For example, as shown in FIG. 2, when the first drive module 31 drives the first plate element 21 to move downward in the second axial direction Y while the second drive module 32 drives the third plate element 23 to move upward in the second axial direction Y, both the first plate element 21 and the third plate element 23 rotate clockwise to form the first rotational motion, while the second plate element 22 rotates counterclockwise to form the second rotational motion. In contrast, when the first drive module 31 drives the first plate element 21 to move upward in the second axial direction Y and the second drive module 32 drives the third plate element 23 to move downward in the second axial direction Y, both the first plate element 21 and the third plate element 23 rotate counterclockwise to form the first rotational motion in the opposite direction, while the second plate element 22 rotates clockwise to form the second rotational motion in the opposite direction. As a result, the three plates 21, 22, 23 have vibrations in two different directions respectively for sensing Coriolis Force in the three axes.

Thus, there is no need to have auxiliary rotating frames in design of the sensor module in the above embodiment. The flexible members required for connecting the frame with the substrate and other plates may also be omitted. However, the vibrations in two different directions can still be achieved.

As to the first plate element 21 being connected with the second plate element 22 and the first drive module 31 respectively by the first flexible member 41 and the third flexible member 43 disposed in an asymmetrically manner mentioned above, it means the numbers of the first and the third flexible members 41, 43 connected with the two sides of the first plate element 21 in the first axial direction X are different, positions of the first and the third flexible members 41, 43 being connected are different, or the types of the first and the third flexible members 41, 43 used for connection (such as flexibility) are different, etc. Similarly, the third plate element 23 is connected with the second plate element 22 and the second drive module 32 respectively by the second flexible member 42 and the fourth flexible member 44 asymmetrically disposed as mentioned above. This means the numbers of the second and the fourth flexible members 42, 44 connected with the two sides of the third plate element 23 in the first axial direction X are different, positions of the second and the fourth flexible members 42, 44 being connected are different, or the types of the second and the fourth flexible members 42, 44 used for connection (such as flexibility) are different, etc. The modifications of the above embodiment fall within the scope of the present application as long as the first drive module 31 and the second drive module 32 can respectively drive the first plate element 21 and the third plate element 23 to have the first rotational motion by the third flexible member 43 and the fourth flexible member 44 and then further drive the second plate element 22 to have a second rotational motion by the first and the second flexible members 41, 42. It should be noted that in a suboptimal arrangement, the first plate element 21 is connected with the second plate element 22 and the first drive module 31 by the first flexible member 41 and the third flexible member 43 which are in a completely symmetrical arrangement. As to the third plate element 23, it is connected with the second plate element 22 and the second drive module 32 by the second flexible member 42 and the fourth flexible member 44 which are in completely symmetrical arrangement. Consequently, it becomes difficult for the three plates 21, 22, 23 to have the two rotational motions corresponding to each other.

The first and the third plate elements 21, 23 preferably have the phase difference of 180 degrees. Those skilled in the art understand that the first embodiment of the three-axis gyroscope may have certain offsets while in use due to influence of factors including process parameters, conditions of power supply, external stress, etc., but it is still within the scope of the present application.

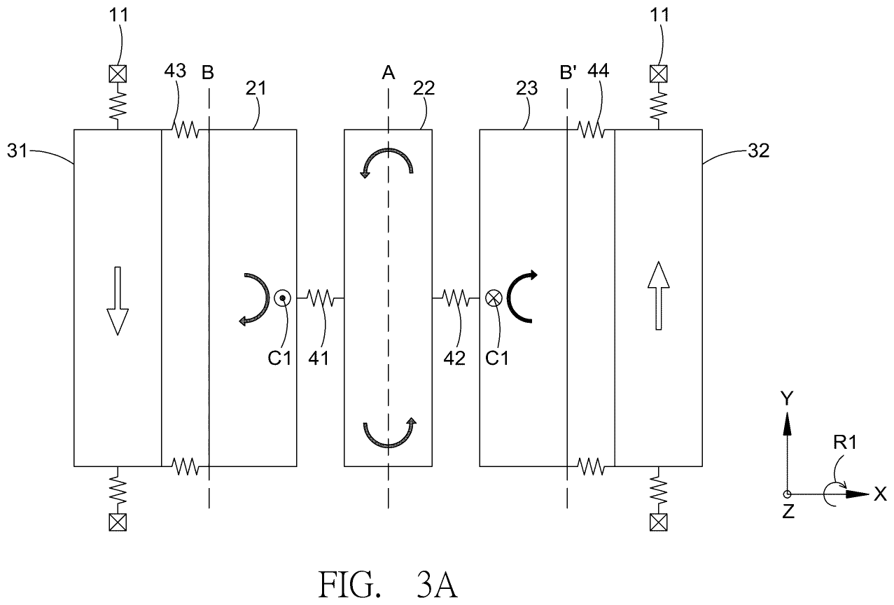

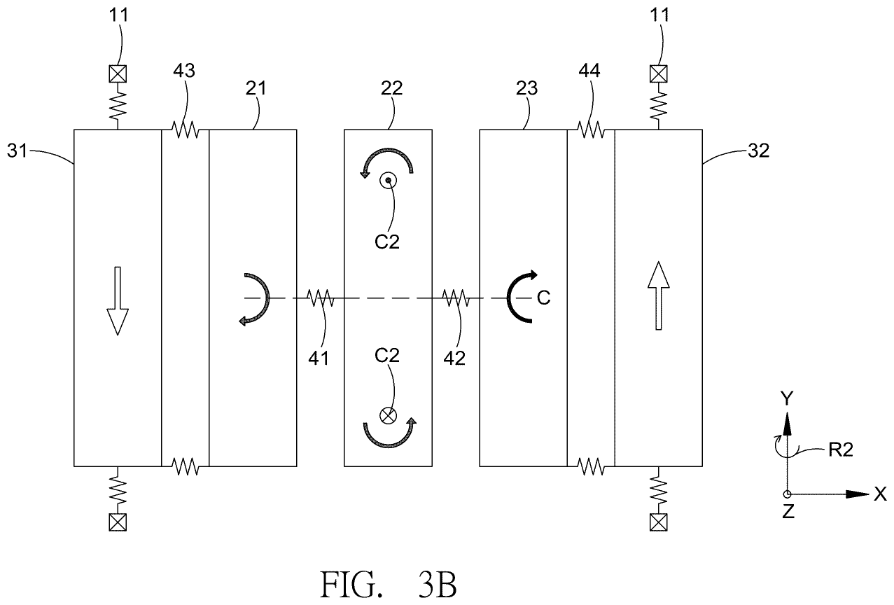

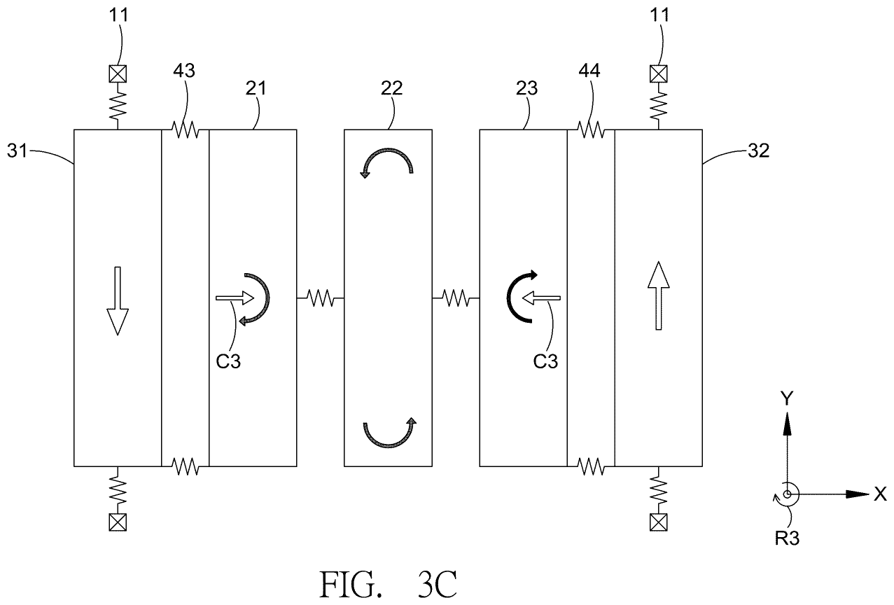

How the first embodiment of the three-axis gyroscope senses rotational motion in three different axes is described in detail below. Referring to FIG. 3A, which provides a schematic drawing showing sensing of rotational motion in the first axial direction. For ease of explanation with simplified figures, the substrate 10 is omitted in FIG. 3A (and also in the following figures). When the gyroscope receives rotational motion R1 in the first axial direction X, a corresponding Coriolis Force C1 is generated at both the first plate element 21 and the third plate element 23, causing the first plate element 21 and the third plate element 23 to have out-of-plane reciprocating movement in B axis and B′ axis respectively (displaced from the X-Y plane formed by the first axial direction X and the second axial direction Y). This then drives the second plate element 22 to have out-of-plane reciprocating movement in A axis. The first and the second drive modules 31, 32 will not move due to connection with the substrate 10 by the positioning members 11. In this case, the rotational motion R1 in the first axial direction X can be sensed by arrangement of corresponding sensing electrodes under the first plate element 21 and the third plate element 23.

Referring to FIG. 3B, a schematic drawing showing sensing of rotational motion in the second axial direction is provided. When the gyroscope receives rotational motion R2 in the second axial direction Y, a Coriolis Force C2 produces an out-of-plane torque on the second plate element 22 so that the second plate element 22 has out-of-plane reciprocating movement in C axis. The first plate element 21 and the third plate element 23 are respectively coupled to the substrate 10 through the first drive module 31 and the second drive module 32. When the second plate element 22 has the above movement, the third flexible member 43 and the fourth flexible member 44 respectively prevent the first plate element 21 and the third plate element 23 from moving along with the second plate element 22. Under such circumstances, the rotational motion R2 in the second axial direction Y may be sensed by arrangement of corresponding sensing electrodes beneath the second plate element 22.

Referring to FIG. 3C, a schematic drawing showing sensing of rotational motion in the third axial direction is provided. When the gyroscope receiving rotational motion R3 in a third axial direction Z, a corresponding Coriolis Force C3 is generated at both the first plate element 21 and the third plate element 23, causing the first plate element 21 and the third plate element 23 to have in-plane reciprocating movement toward or away from the second plate element 22 and the first and second drive modules 31, 32 in opposite directions (parallel to the X-Y plane). At this moment, only the first flexible member 41 between the first plate element 21 and the second plate element 22 and the second flexible member 42 between the third plate element 23 and the second plate element 22 are deformed, while the second plate element 22 does not moved along with the first and the third plate elements 21, 23. As for the first and the second drive modules 31, 32 fixed on the substrate 10 by the positioning members 11, they also do not move. Thereby, the rotational motion R3 in the third axial direction Z may be sensed by arrangement of corresponding sensing electrodes in the first plate element 21 and the third plate element 23.

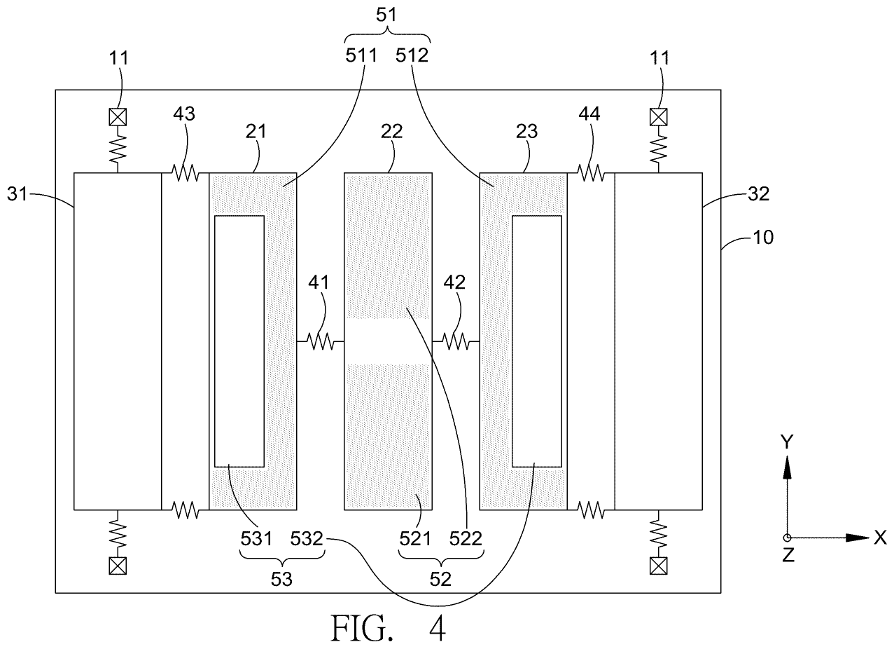

In the above first embodiment, there are various ways of arranging the sensing electrodes. Referring to FIG. 4, a set of first out-of-plane sensing electrodes 51 is disposed beneath the first plate element 21 (511) and beneath the third plate element 23 (512) for sensing the rotational motion in the first axial direction X. A set of second out-of-plane sensing electrodes 52 is disposed beneath the second plate element 22 (521, 522) for sensing the rotational motion in the second axial direction Y. A set of in-plane sensing electrodes 53 is mounted in the first plate element 21 (531) and the third plate element 23 (532) for sensing the rotational motion in the third axial direction Z. When the gyroscope senses rotational motion in the first axial direction X, the second axial direction Y, and the third axial direction Z, a Coriolis Force C1 is generated at the respective plates 21, 22, 23 correspondingly, causing the respective plates 21, 22, 23 to have in-plane or out-of-plane reciprocating movement correspondingly. The sensing method of the above sets of sensing electrodes 51, 52, 53 is capacitive sensing. By disposition of the set of the in-plane sensing electrodes 53 and the sets of the first and the second out-of-plane sensing electrodes 51, 52 on the respective plates 21, 22, 23 or the substrate 10 correspondingly, the sets of the sensing electrodes 51, 52, 53 form differential electrodes to eliminate common mode noise which is not part of the sensing signals.

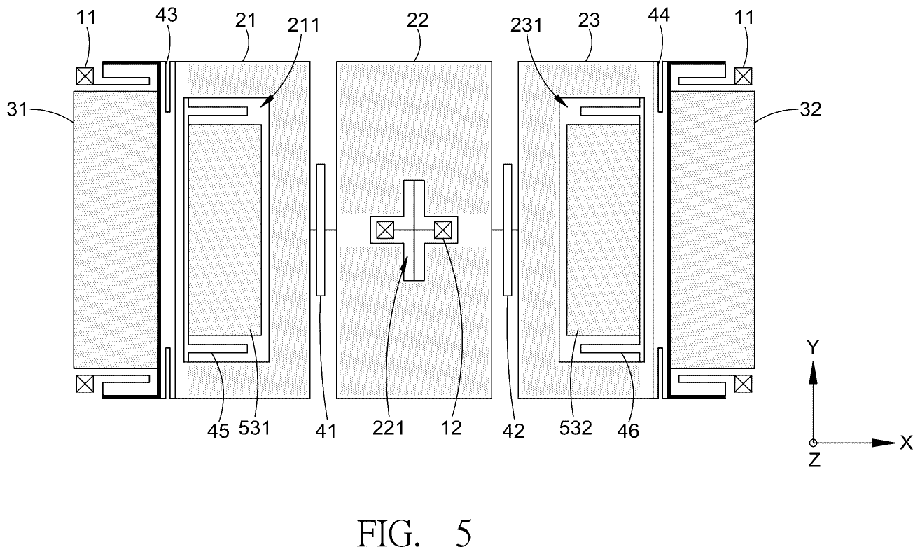

Referring to FIG. 5, a schematic drawing showing the structure of an embodiment according to the present application is provided. The second plate element 22 may also be provided with positioning members 12 such as a flexible member or an anchor point therein. For example, the second plate element 22 is provided with an insertion hole 221 therein, as shown in FIG. 5. An inner edge of the second plate element 22 around the insertion hole 221 may be connected with anchor points by flexible members to form the positioning members 12 in the insertion hole 221. The positioning members 12 may be used as structural support not only for assistance in the second rotational motion of the second plate element 22 mentioned above but also for decreasing the possibility of the second plate element 22 having unexpected motion.

Moreover, in this embodiment, the first plate element 21 and the third plate element 23 are respectively provided with an insertion hole 211 and an insertion hole 231 for mounting the in-plane sensing electrode 531 and the in-plane sensing electrode 532 mentioned above correspondingly. An inner edge of the first plate element 21 around the insertion hole 211 may be connected with the in-plane sensing electrode 531 by a fifth flexible member 45 while an inner edge of the third plate element 23 around the insertion hole 231 may be connected with the in-plane sensing electrode 532 by a sixth flexible member 46. Thereby, the fifth and the sixth flexible members 45, 46 allow the in-plane sensing electrodes 531, 532 to move in the second axial direction Y or the third axial direction Z and have displacement. Thus, the sensing electrode 53 focuses on sensing reciprocating movement of the first plate element 21 and the third plate element 23 in the first axial direction X and enhances the ability of the in-plane sensing electrodes 531, 532 to form differential electrodes for elimination of common mode noise which is not part of the sensing signal.

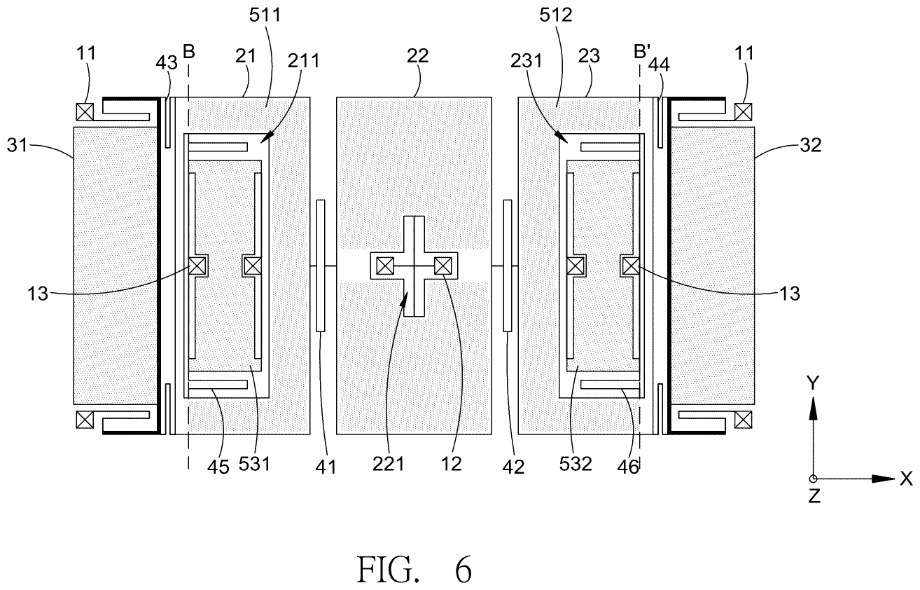

Referring to FIG. 6, a schematic drawing showing another structure of an embodiment according to the present application is provided. The difference between this structure and the above one is that at least one positioning member 13 such as a flexible member or an anchor point is mounted in the first plate element 21 and the third plate element 23. As shown in the figure, the in-plane sensing electrode 531 in the first plate element 21 is not only connected with an anchor point 13 but also connected with the first out-of-plane sensing electrode 511 by the fifth flexible member 45. Similarly, the in-plane sensing electrode 532 in the third plate element 23 is not only connected with an anchor point 13 but also connected with the first out-of-plane sensing electrode 512 by the sixth flexible member 46. Such an arrangement may allow the designer to adjust precise positions of the B axis and the B′ axis during out-of-plane reciprocating movement of the first plate element 21 and the third plate element 23 in the B axis and the B′ axis respectively. Consequently, not only can in-phase rotational motion of the first plate element 21 and the third plate element 23 within the operation bandwidth of the gyroscope be avoided, but rotation coupling between the in-plane sensing electrode 53 and driving displacement is also reduced. Thus, overall sensing performance is improved.

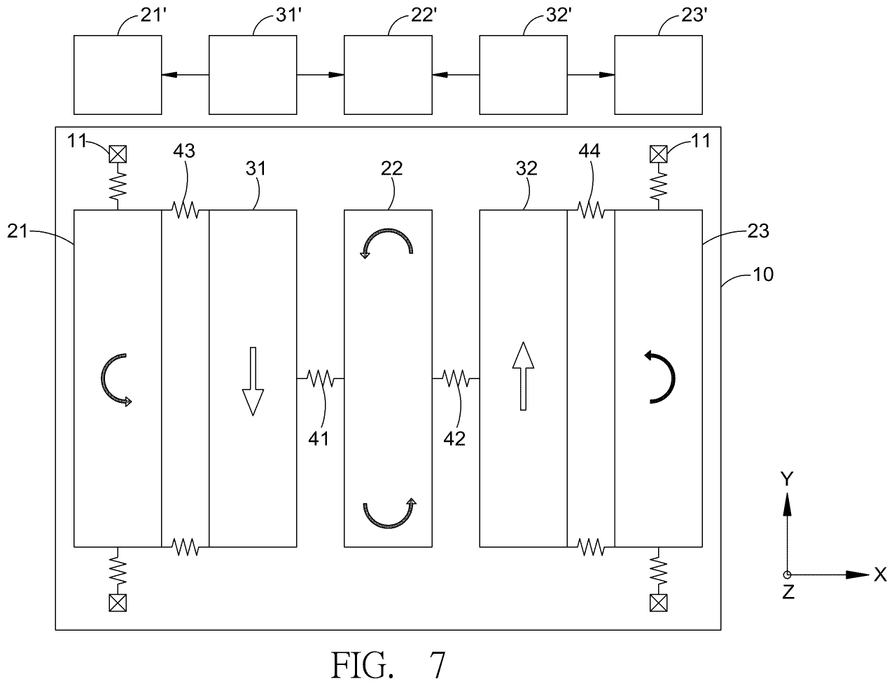

As shown in FIG. 7, a schematic drawing showing action of another embodiment is provided. Unlike the above embodiment, drive modules in this embodiment are not limited to being disposed on an outer side of the respective three plates. The drive modules may be disposed between the three plates and preferably also in an axial direction. A corresponding displacement and velocity generated by the drive modules are directly coupled to the three plates so that the three plates generate two rotational motions correspondingly. Thus, vibrations in two different directions are achieved for performing three-axis sensing of Coriolis force.

In more detail, in this embodiment, the second plate element 22 is disposed between the first drive module 31 and the second drive module 32 in the first axial direction X, while the first plate element 21 is disposed on one side of the first drive module 31 away from the second plate element 22 in the first axial direction X, and the third plate element 23 is disposed on one side of the second drive module 32 away from the second plate element 22 in the first axial direction X. Thereby, the first plate element 21, the first drive module 31, the second plate element 22, the second drive module 32, and the third plate element 23 are disposed along the first axial direction X.

An outer edge of the first drive module 31 is connected with an outer edge of the second plate element 22 by a first flexible member 41. An outer edge of the second drive module 32 is connected with an outer edge of the second plate element 22 by a second flexible member 42. The first flexible member 41 and the second flexible member 42 are located on two sides of the second plate element 22 correspondingly in the first axial direction X. The first plate element 21 is connected with the first drive module 31 by a third flexible member 43 and fixed on the substrate 10 by positioning members 11 such as a flexible member or an anchor point. The first plate element 21 and the second plate element 22 are disposed on two sides of the first drive module 31 correspondingly in the first axial direction X. The third plate element 23 is connected with the second drive module 32 by a fourth flexible member 44 and fixed on the substrate 10 by positioning members 11 such as a flexible member or an anchor point. The third plate element 23 and the second plate element 22 are disposed on two sides of the second drive module 32 correspondingly in the first axial direction X.

The first plate element 21 is connected with the first drive module 31 by the third flexible member 43, allowing it to be driven by the first drive module 31 to have reciprocating movement in the second axial direction Y. The third plate element 23 is connected with the second drive module 32 by the fourth flexible member 44 for being driven by the second drive module 32 to have reciprocating movement in the second axial direction Y. The direction in which the first plate element 21 is driven by the first drive module 31 is preferably opposite to the direction of the third plate element 23 being driven by the second drive module 32. This means the first and the third plate elements 21, 23 have the phase difference of 180 degrees to form vibrations in opposite directions. FIG. 7 is a schematic drawing showing transfer of driving force. In this embodiment, the first drive module 31′ and the second drive module 32′ respectively actuate the first plate element 21′ and the third plate element 23′ while the second plate element 22′ between the first and the second drive modules 31′, 32′ is also driven by the first and the second drive modules 31′, 32′ together.

It should be noted that the first drive module 31 is connected with the second plate element 22 and the first plate element 21 respectively by the first flexible member 41 and the third flexible member 43 which are asymmetrically disposed. The second drive module 32 is connected with the second plate element 22 and the third plate element 23 respectively by the second flexible member 42 and the fourth flexible member 44 which are asymmetrically disposed. Consequently, the first plate element 21 and the third plate element 23 have a corresponding first rotational motion during the driving of the first drive module 31 and the second drive module 32. At the same time, the second plate element 22 has a corresponding second rotational motion. Therefore, the three plates 21, 22, 23 have the two rotational motions correspondingly.

The detailed operation principle and various implementations of the second embodiment are similar to those of the first embodiment. People having ordinary skill in the art may understand the second embodiment by referring to the above specification and corresponding figures.

In summary, the present three-axis gyroscope does not require common auxiliary rotating frames for sensing modules, thus eliminating the need for flexible members to connect the frame with the substrate and other plate. However, vibrations in two different directions are still provided to achieve three-axis sensing of Coriolis force. Moreover, the respective embodiments of the present application incorporate simplified coupling flexible structures to reduce the overall area of the gyroscope. The reduced number of the flexible members and frame-less design not only optimize effective sensing area of the original plates, but also make the original flexible members have better fabrication tolerance without significant reduction in line width of the original flexible members. Thereby, production costs are reduced and yield rates are improved.

Therefore, the present application solves various problems caused by the frames and related coupling flexible structures and the present application which is novel, non-obvious, and useful meets major requirements for patentability.

Additional advantages and modifications will readily occur to those skilled in the art. Therefore, the invention in its broader aspects is not limited to the specific details, and representative devices shown and described herein. Accordingly, various modifications may be made without departing from the spirit or scope of the general inventive concept as defined by the appended claims and their equivalents.

1. A three-axis gyroscope, comprising:
a substrate on which a first plate element, a second plate element, a third plate element, a first drive module, and a second drive module are disposed;
wherein the first drive module, the first plate element, the second plate element, the third plate element, and the second drive module are disposed along a first axial direction;
wherein the first plate element is connected with the second plate element by a first flexible member while the third plate element is connected with the second plate element by a second flexible member; the first flexible member and the second flexible member are located on two sides of the second plate element correspondingly in the first axial direction;
wherein the first drive module is connected with the first plate element by a third flexible member for driving the first plate element to reciprocate in a second axial direction while the second axial direction is perpendicular to the first axial direction; the second drive module is connected with the third plate element by a fourth flexible member for driving the third plate element to reciprocate in the second axial direction.

2. The three-axis gyroscope as claimed in claim 1, wherein the first flexible member and the third flexible member are connected with two sides of the first plate element correspondingly in the first axial direction and disposed in an asymmetric manner with respect to the first plate element; the second flexible member and the fourth flexible member are connected with two sides of the third plate element correspondingly in the first axial direction and disposed in an asymmetric manner with respect to the third plate element.

3. The three-axis gyroscope as claimed in claim 1, wherein there is a phase difference of 180 degrees between a direction of the first plate element driven to reciprocate by the first drive module and a direction of the third plate element driven to reciprocate by the second drive module.

4. The three-axis gyroscope as claimed in claim 1, wherein the first plate element and the third plate element have a first rotational motion correspondingly while respectively being driven by the first drive module and the second drive module.

5. The three-axis gyroscope as claimed in claim 4, wherein the first plate element and the third plate element drive the second plate element respectively through the first flexible member and the second flexible member so that the second plate element has a second rotational motion correspondingly.

6. The three-axis gyroscope as claimed in claim 1, wherein the three-axis gyroscope further includes:
a set of first out-of-plane sensing electrodes disposed under the first plate element and under the third plate element correspondingly for sensing rotational motion in the first axial direction;
a set of second out-of-plane sensing electrodes disposed under the second plate element for sensing rotational motion in the second axial direction; and
a set of in-plane sensing electrodes mounted in the first plate element and the third plate element correspondingly for sensing rotational motion in the third axial direction.

7. The three-axis gyroscope as claimed in claim 6, wherein the first plate element is provided with an insertion hole for mounting one of the in-plane sensing electrodes while the third plate element is provided with another insertion hole for mounting the other one of the in-plane sensing electrodes; an inner edge of the first plate element around the insertion hole is connected with the one of the in-plane sensing electrodes by a fifth flexible member while an inner edge of the third plate element around the another insertion hole is connected with the other one of the in-plane sensing electrodes by a sixth flexible member.

8. The three-axis gyroscope as claimed in claim 6, wherein the first plate element is provided with an insertion hole for mounting one of the in-plane sensing electrodes and the one of the in-plane sensing electrodes is connected with an anchor point; the third plate element is provided with another insertion hole for mounting the other one of the in-plane sensing electrodes and the other one of the in-plane sensing electrodes is connected with another anchor point; wherein one of the first out-of-plane sensing electrodes disposed under the first plate element is connected with the one of the in-plate sensing electrodes by a fifth flexible member while the other one of the first out-of-plane sensing electrodes disposed under the third plate element is connected with the other one of the in-plate sensing electrodes by a sixth flexible member.

9. The three-axis gyroscope as claimed in claim 1, wherein the second plate element is provided with an insertion hole therein and an inner edge of the second plate element around the insertion hole is connected with at least one anchor point by at least one flexible member.

10. The three-axis gyroscope as claimed in claim 1, wherein the first drive module and the second drive module are fixed on the substrate by at least one positioning member.

11. A three-axis gyroscope comprising:
a substrate on which a first plate element, a second plate element, a third plate element, a first drive module, and a second drive module are disposed;
wherein the first plate element, the first drive module, the second plate element, the second drive module, and the third plate element are disposed along a first axial direction;
wherein the first drive module is connected with the second plate element by a first flexible member and the second drive module is connected with the second plate element by a second flexible member while the first flexible member and the second flexible member are located on two sides of the second plate element correspondingly in the first axial direction;
wherein the first drive module is connected with the first plate element by a third flexible member for driving the first plate element to have reciprocating movement in a second axial direction while the second axial direction is perpendicular to the first axial direction; the second drive module is connected with the third plate element by a fourth flexible member for driving the third plate element to have reciprocating movement in the second axial direction.

12. The three-axis gyroscope as claimed in claim 11, wherein the first flexible member and the third flexible member are connected with two sides of the first drive module correspondingly in the first axial direction and disposed in an asymmetric manner with respect to the first drive module; the second flexible member and the fourth flexible member are connected with two sides of the second drive module correspondingly in the first axial direction and disposed in an asymmetric manner with respect to the second drive module.

13. The three-axis gyroscope as claimed in claim 11, wherein there is a phase difference of 180 degrees between a direction of the first plate element driven to have reciprocating movement by the first drive module and a direction of the third plate element driven to have reciprocating movement by the second drive module.

14. The three-axis gyroscope as claimed in claim 11, wherein the first plate element and the third plate element have a first rotational motion correspondingly while respectively being driven by the first drive module and the second drive module.

15. The three-axis gyroscope as claimed in claim 14, wherein the first drive module and the second drive module drive the second plate element respectively through the first flexible member and the second flexible member so that the second plate element has a second rotational motion correspondingly.

16. The three-axis gyroscope as claimed in claim 11, wherein the first plate element and the third plate element are fixed on the substrate by a positioning member.
